(19) United States
(12) Patent Application Publication
(10) Pub. No.: US 2010/0244044 A1
(43) Pub. Date: Sep. 30, 2010

(54) GaN-BASED FIELD EFFECT TRANSISTOR

(75) Inventors: Jiang Li, Tokyo (JP); Masayuki Iwami, Tokyo (JP)

Correspondence Address: TUROCY & WATSON, LLP, 127 Public Square, 57th Floor, Key Tower, CLEVELAND, OH, 44114, US

(73) Assignee: FURUKAWA ELECTRIC CO., LTD, Tokyo (JP)

(21) Appl. No.: 12/730,941

(22) Filed: Mar. 24, 2010

(30) Foreign Application Priority Data
Mar. 25, 2009 (JP) 2009-073446

(51) Int. Cl. H01L 29/20

(52) U.S. Cl. 257/76; 257/E29.089

(57) ABSTRACT

The invention provides a GaN-based compound semiconductor device that is operable with low ON-resistance and high withstanding voltage. The GaN-based field effect transistor includes a buffer layer formed on a substrate, a channel layer, a drift layer formed on the channel layer, source and drain electrodes formed on the drift layer, an insulating film formed on the inner surface of a recess form in the drift layer and on the surface of the drift layer and a gate electrode formed on the insulating film and having a field plate portion. The drift layer has a reducing surface field region composed of n-type GaN-based compound semiconductor whose sheet carrier density is more than 5×10¹³ cm⁻² and less than 1×10¹⁴ cm⁻² between the recess and the drain electrode and thickness of the insulating film formed on the reducing surface field region of the drift layer is 300 nm or more.

### CROSS-REFERENCE TO RELATED APPLICATIONS

This application claims priority from Japanese patent application serial No. 2009-073446, filed on Mar. 25, 2009, the entire content of which is incorporated herein by reference.

### BACKGROUND OF THE INVENTION

1. Field of the Invention

The present invention relates to a GaN-based field effect transistor (FET) used as a power electronic device and a high-frequency amplifying device.

2. Related Art

A wideband gap semiconductor typified by a III-nitride compound semiconductor is very attractive as a material of a semiconductor device use for high-temperature environment, large power or high-frequency because it has a high breakdown voltage, favorable electron transporting characteristic and favorable thermal conductivity.

Patent Document 1 discloses that a parasitic capacitance may be reduced, a value of return loss may be lowered, a breakdown voltage may be improved and a strain level to an excessive input may be lowered in a high-frequency and large output Schottky gate field effect transistor by forming a gate electrode having a predetermined marked field plate portion on a dielectric film having a predetermined thickness.

Still more, a so-called normally-off type FET in which no current flows in the device when no control signal (voltage) is applied to a gate is normally used in an inverter and a converter used in controlling electric power. Patent Document 2 discloses a device in which a contact layer and a RESURF (reducing surface field) layer are selectively grown again in a MOS (Metal Oxide Semiconductor) type field effect transistor (MOSFET) having a normally-off structure.

However, the MOSFET disclosed in the Patent Document 2 has had a problem that the withstanding voltage drops sharply if carrier density of the resurf layer is increased to reduce ON-resistance of the device. This is considered to happen when the carrier density of the resurf layer is high because concentration of field occurs between the end on the drain side of the gate electrode and the resurf layer, thus causing a dielectric breakdown.

[Patent Document 1] Japanese Patent Application Publication No. 2000-118122

[Patent Document 2] Japanese Patent Application Publication No. 2008-159631

### SUMMARY OF THE INVENTION

In view of the problems described above, the present invention aims at providing a GaN-based compound semiconductor that may be operated with low ON-resistance and high Breakdown voltage.

A GaN-based field effect transistor according to one aspect of the invention includes: a substrate; a buffer layer formed on the substrate; a channel layer formed on the buffer layer and composed of p-type GaN-based compound semiconductor; a drift layer formed on the channel layer, composed of n-type GaN-based compound semiconductor and having a concave recess that reaches the channel layer at a part thereof; source and drain electrodes formed on the drift layer so as to be electrically connected with the drift layer and so as to interpose the recess; an insulating film formed on the inner surface of the recess and on the surface of the drift layer; and a gate electrode formed on the insulating film and having a field plate portion; wherein the drift layer has a field reducing region composed of n-type GaN-based compound semiconductor whose sheet carrier density is more than 5×10¹³ cm⁻² and less than 1×10¹⁴ cm⁻² between the recess and the drain electrode and thickness of the insulating film formed on the field reducing region of the drift layer is 300 nm or more.

The invention described above brings about such a remarkable effect that the high breakdown voltage may be obtained even if the carrier density of the resurf region is increased to lower the ON-resistance by thickening the insulating film of the field plate portion in the field effect transistor having the gate field plate structure.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a sectional schematic view of a GaN-based field effect transistor according to a first embodiment of the invention;

FIG. 2 is a graph showing a relationship between sheet carrier density of a resurf region and breakdown voltage of the GaN-based field effect transistor of the first embodiment of the invention;

FIG. 3 is a sectional diagrammatic view showing one exemplary method for fabricating the GaN-based field effect transistor of the first embodiment of the invention;

FIG. 4 is a sectional diagrammatic view showing the exemplary method for fabricating the GaN-based field effect transistor of the first embodiment of the invention;

FIG. 5 is a sectional diagrammatic view showing the exemplary method for fabricating the GaN-based field effect transistor of the first embodiment of the invention;

FIG. 6 is a sectional diagrammatic view showing the exemplary method for fabricating the GaN-based field effect transistor of the first embodiment of the invention;

FIG. 7 is a sectional diagrammatic view showing the exemplary method for fabricating the GaN-based field effect transistor of the first embodiment of the invention;

FIG. 8 is a sectional diagrammatic view showing the exemplary method for fabricating the GaN-based field effect transistor of the first embodiment of the invention;

FIG. 9 is a sectional schematic view of a GaN-based field effect transistor according to a second embodiment of the invention; and

FIG. 10 is a sectional schematic view of a GaN-based field effect transistor according to a third embodiment of the invention.

### DETAILED DESCRIPTION OF THE PREFERRED EMBODIMENTS

Each embodiment shaping the present invention will be explained with reference to the drawings. It is noted that the same or corresponding parts in the respective embodiments will be denoted by the same reference numerals and overlapped explanation thereof will be omitted here.

### First Embodiment

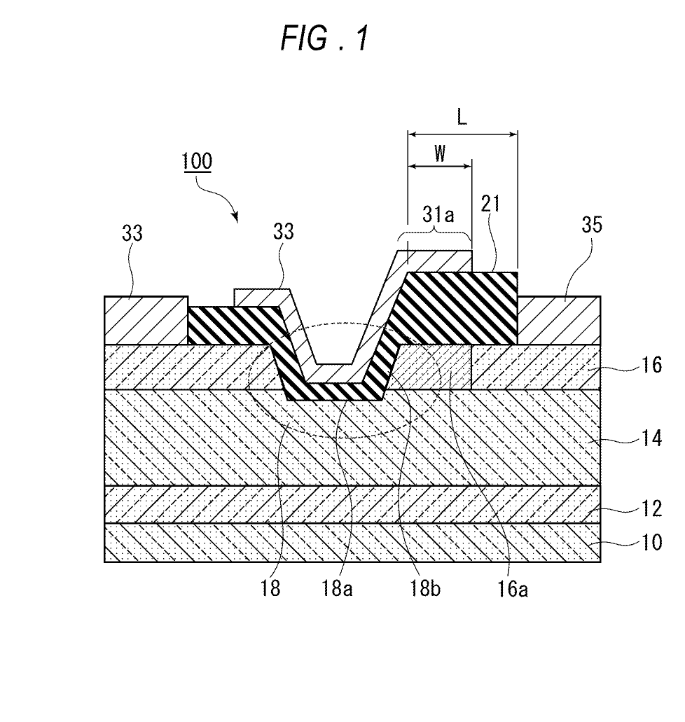

FIG. 1 is a sectional diagrammatic view of a GaN-based field effect transistor (referred to as a ‘MOSFET’ hereinafter) according to a first embodiment of the invention. As shown in FIG. 1, the MOSFET 100 is formed by sequentially laminating a buffer layer 12 formed by alternately laminating GaN layers and AlN layers, a channel layer 14 composed of p-type GaN and a drift layer 16 composed of n-type GaN on a substrate 10 composed of silicon (Si), silicon carbide (SiC), sapphire or the like.

A recess 18 whose bottom 18a reaches the channel layer 14 and whose cross-section is substantially inverted trapezoidal is provided in a part of the drift layer 16. An inner side surface 18b of the recess rises while inclining with respect to the bottom 18a.

An insulating film 21 is formed on the surface of the drift layer 16, the bottom 18a and the inner side surface 18b of the recess 18, and a gate electrode 31 is formed on the insulating film 21 in the recess 18. Further, source electrode 33 and drain electrodes 35 are formed on the drift layer 16 interposing the recess 18 so that they ohmically contact with the drift layer 16, respectively.

The drift layer 16 is provided with a resurf region 16a (reducing surface field region) whose sheet carrier density is lower than that of other part of the drift layer 16. The resurf region 16a has a function of reducing the concentration of electric field generated between the gate electrode 31 and the drain electrode 35. The gate electrode 31 has a field plate (FP) portion 31a on the resurf region 16a through the insulating film 21. The field plate portion 31a has a function of reducing concentration of electric field generated at an end on the drain side of the gate electrode 31.

The sheet carrier density of the resurf region 16a is required to be more than 5×10¹³ cm⁻² and less than 1×10¹⁴ cm⁻² in order to acquire favorable breakdown voltage. The sheet carrier density is not preferable if it is lower than 5×10¹³ cm⁻² because the ON-resistance of the FET increases. The sheet carrier density is also not preferable if it is higher than 1×10¹⁴ cm⁻² because the breakdown voltage drops as described later.

The thickness of the insulating film 21 formed on the resurf region 16a is preferable to be more than 300 nm and in such a case, a value of 1500 V or more may be acquired as the breakdown voltage of the FET. Although an upper limit of the thickness of the insulating film 21 formed on the resurf region 16a is not specifically limited, it is preferable to be around 1500 nm, taking a fabrication time and others into consideration.

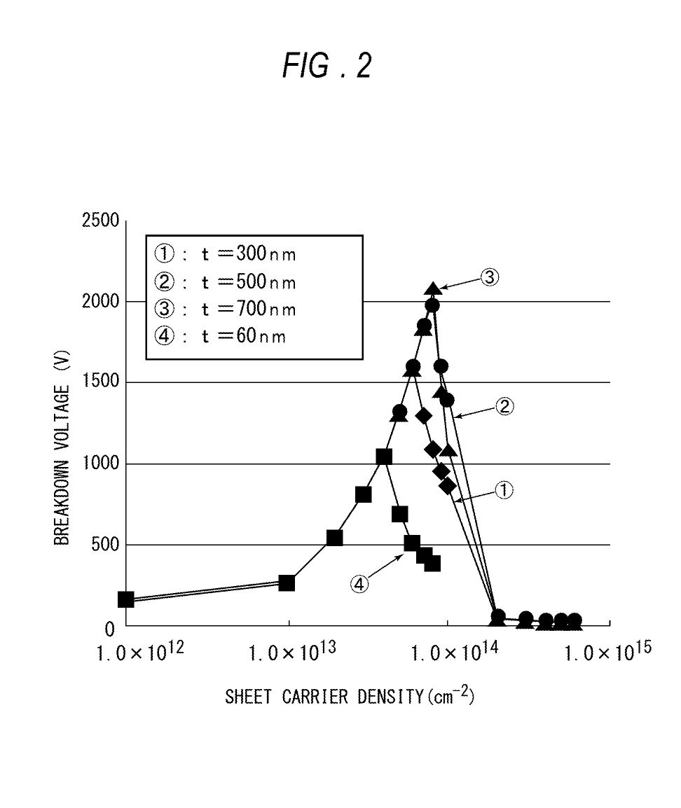

FIG. 2 is a graph showing a relationship between the sheet carrier density of the resurf region 16a and the breakdown voltage of the MOSFET in the GaN-based field effect transistor of the first embodiment of the invention. ‘t’ in the graph denotes the thickness of the insulating film 21 on the resurf region 16a. As shown in FIG. 2, the breakdown voltage of the device has the maximum value (referred to as a ‘maximum breakdown voltage’ hereinafter) with respect to the sheet carrier density of the resurf region 16a and the maximum breakdown voltage increases as the value of t increases.

However, when the thickness of the insulating film 21 on the resurf region 16a is 60 nm, the breakdown voltage (withstanding voltage) of the device is maximized when the sheet carrier density of the resurf region 16a is around 4.0×10¹³ cm⁻² and the breakdown voltage drops sharply when the sheet carrier density is more than that. This is considered to happen because the concentration of electric field occurs between the end on the drain electrode 35 side of the gate electrode 31 and the resurf region 16a, causing a dielectric breakdown.

When the sheet carrier density of the drift layer 16 is lower than 5.0×10¹³ cm⁻², the ON-resistance cannot be fully reduced and the breakdown voltage of the device is lowered as low as 1,000 V or less even if the thickness of the insulating film 21 on the resurf region 16a is increased. When the carrier density of the drift layer 16 is higher than 1.0×10¹⁴ cm⁻², although the ON-resistance drops, the breakdown voltage is also lowered.

From the reasons described above, the sheet carrier density of the drift layer 16 is preferable to be more than 5×10¹³ cm⁻² and less than 1×10¹⁴ cm⁻² and the thickness of the insulating film 21 on the resurf region 16a is preferable to be 300 nm or more. It is thus possible to obtain the low ON-resistance and high breakdown voltage field effect transistor by constructing as described above.

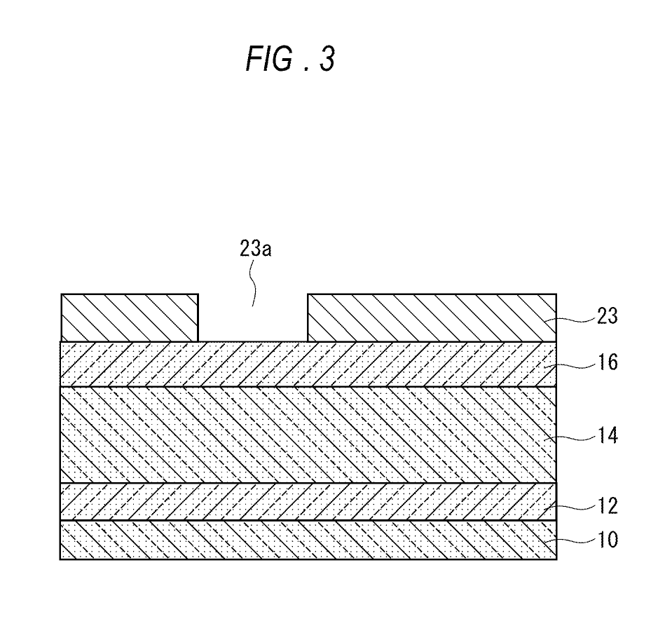

Next, a method for fabricating the GaN-based field effect transistor of the first embodiment of the invention will be explained. FIGS. 3 through 8 are schematic views for explaining the method for fabricating the MOSFET 100 shown in FIG. 1. It is noted that although one fabricated by using metal organic chemical vapor deposition (MOCVD) will be explained below, the invention is not specifically limited to that method.

At first, the substrate 10 having a (111) plane as the main surface is set in a MOCVD apparatus and the buffer layer 12 and the channel layer 14 composed of the p-type GaN are epitaxially grown sequentially on the substrate 10 by using hydrogen gas as carrier gas and trimethyl-gallium (TMGa), trimethyl-aluminum (TMAl) and ammonia (NH₃) as raw gas at 1050° C. of growth temperature. It is noted that biscyclopentadienyl-magnesium (CP₂Mg) is used as a p-type doping source for the channel layer 14 and a flow rate of CP₂Mg is controlled so that density of Mg becomes around 1×10¹⁶ cm⁻³. Next, TMGa and NH₃ are introduced into the MOCVD system to epitaxially grow the drift layer 16 on the channel layer 14 at 1050° C. of growth temperature. Sheet carrier density of the drift layer 16 composed of n⁻-type GaN is around 1.0×10¹⁴ cm².

It is noted that the buffer layer 12 described above is formed by laminating eight composite layers of GaN/AlN each having a thickness of 200 nm/20 nm. Still more, the thicknesses of the buffer layer 12, the channel layer 14 and the drift layer 16 are 1800 nm, 600 nm and 100 nm, respectively.

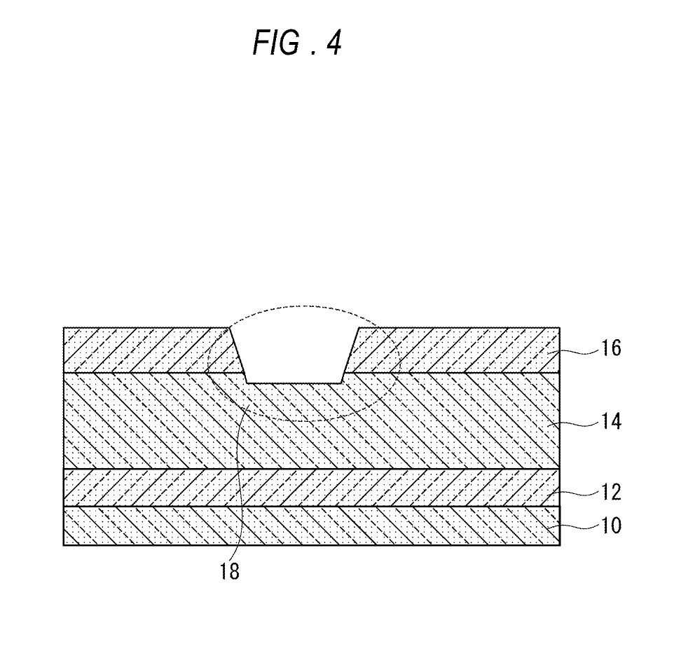

Further, a first mask layer 23 composed of amorphous silicon (a-Si) of 500 nm thick is formed on the drift layer 16 by using plasma chemical vapor deposition (PCVD) and patterning is carried out by using photolithography and CF₄ gas to form an opening 23a as shown in FIG. 3. Still more, the drift layer 16 is etched by using the first mask layer 23 as a mask and Cl₂ gas to form the recess 18 whose bottom reaches the channel layer 14 as shown in FIG. 4. Preferably, the cross-section of the recess 18 is formed into a substantially inverted trapezoidal shape in which at least the side surface on the side where the drain electrode is formed rises while being inclined with respect to the bottom. Such configuration permits to suppress the electric field from concentrating at the end on the drain electrode side of the bottom of the recess and to acquire higher breakdown voltage.

It is noted that because the first mask layer 23 is etched from the upper surface, the thickness of the first mask layer 23 is fully thickened so that the drift layer 16 is not exposed at locations other than the opening 23a when the drift layer 16 is etched until when the channel layer 14 is exposed.

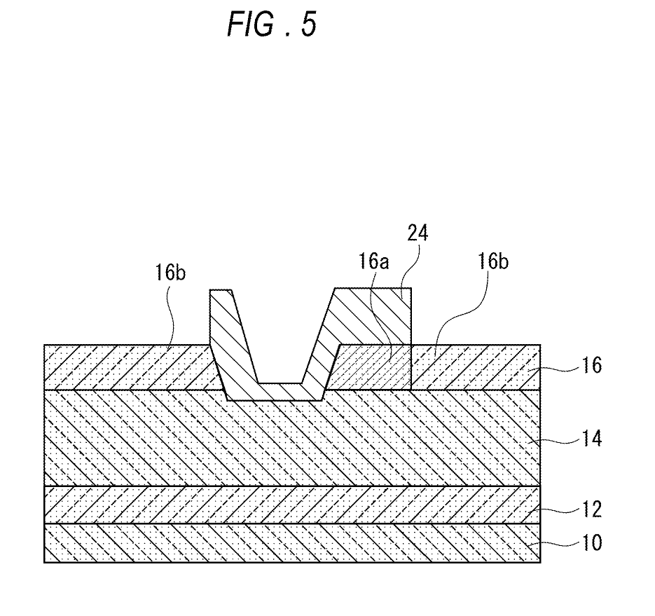

Next, after removing the first mask layer 23, a second mask layer 24 covering the recess 18 and a part of the drift layer 16 is formed and n-type impurity is ion-implanted to parts of the drift layer 16 where the source electrode 33 and the drain electrode 35 are to be formed to form a contact region 16b composed of n′-type GaN. At this time, the remaining part of the drift layer 16 not ion-implanted becomes the resurf region 16a as shown in FIG. 5. Here, because the sheet carrier density of the contact region 16b reduces contact resistance with ohmic electrodes (the source electrode 33 and the drain electrode 35), it is preferable to be 1×10¹⁸ cm⁻³ or more.

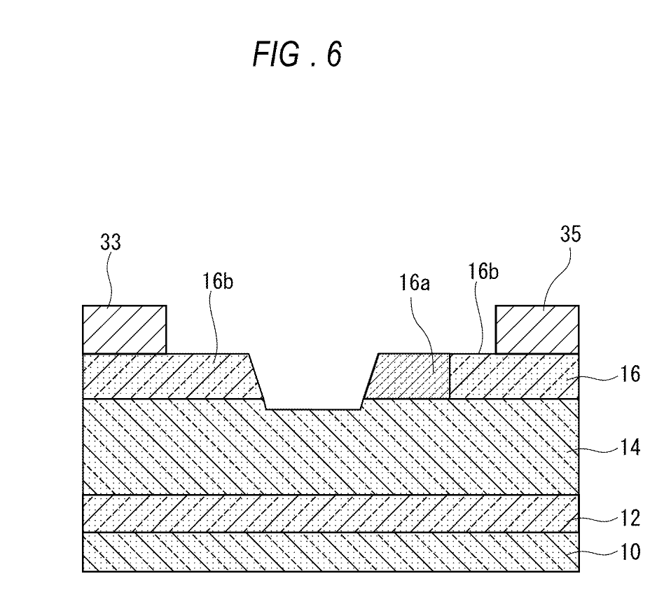

Next, after removing the second mask layer 24, the source and drain electrodes 33 and 35 are formed on the contact regions 16b by using a lift-off process as shown in FIG. 6. It is noted that the both of the source electrode 33 and drain electrodes 35 are composed of a Ti/Al laminated structure having 25 nm/300 nm of thickness. Further, a metal film composing the electrodes may be formed by using sputtering and vacuum vapor deposition.

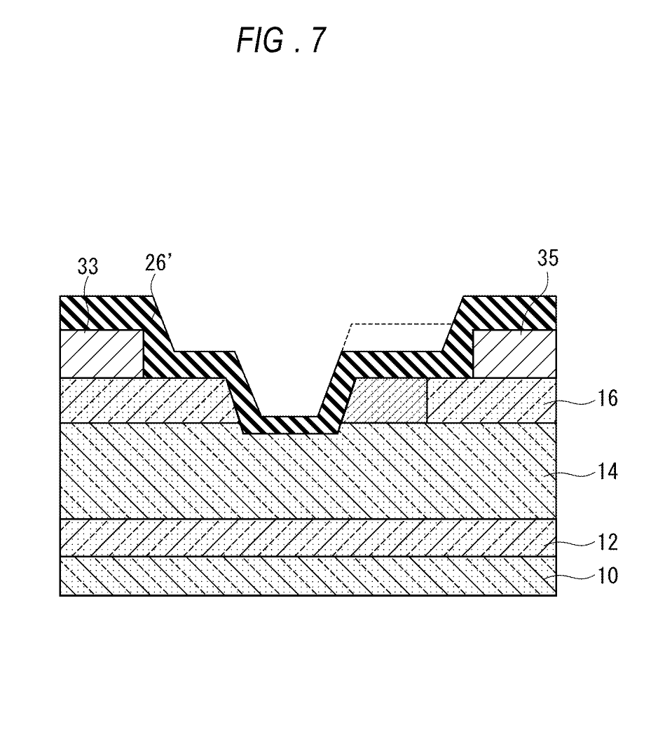

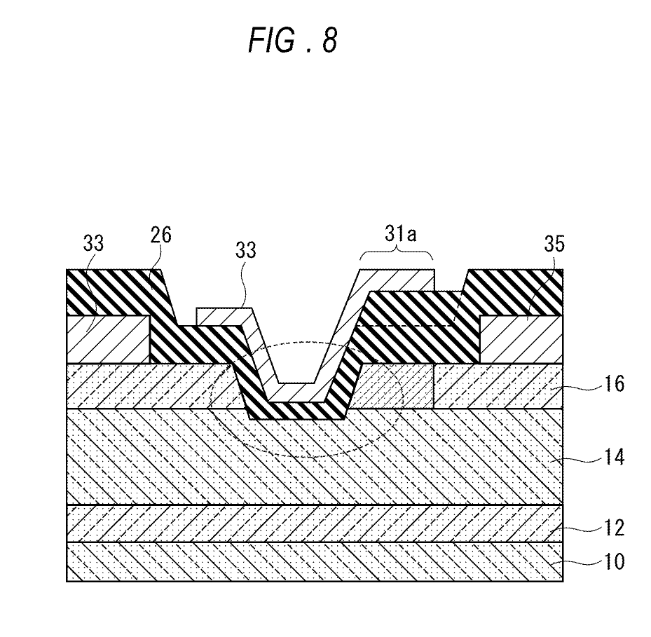

Next, an insulating film 26′ composed of SiO₂ and having 60 nm of thickness is formed on the inner surface of the recess 18, on the drift layer 16, the source electrode 33 and drain electrodes 35 by using PCVD and SiH₄ and N₂O as its materials as shown FIG. 7. Still more, SiO₂ is formed only on the resurf region 16a to form the insulating film 26. At this time the insulating film on the resurf region 16a is formed to be 300 nm or more in total as shown in FIG. 8.

Next, the gate electrode 31 having the Ti/Al laminated structure is formed on the insulating film 26 in the recess 18 by using the lift-off process and then the insulating film 26 on the source electrode 33 and drain electrodes 35 is removed. Thereby, the MOSFET 100 as shown in FIG. 1 is completed.

Here, the end on the drain electrode 35 side of the gate electrode 31 is provided with the field plate portion 31a while interposing the insulating film on the resurf region 16a, so that the breakdown voltage may be improved further. While a length ‘W’ of the field plate portion 31a may be appropriately determined depending on a distance between the gate electrode 31 and the drain electrode 35, it is preferable to be L/3 when the distance between the gate electrode 31 and the drain electrode 35 is ‘L’. For instance, when ‘L’ is 12 μm, ‘W’ is preferably around 4 μm (see FIG. 1).

Still more, the length ‘W’ of the field plate portion 31a is preferable to be more than 0.5 μm and less than 10 μm. That is, if ‘W’ is shorter than 0.5 μm, it becomes difficult to obtain the field plate effect and if it is longer than 10 μm, the distance between the gate and the drain becomes long, enlarging the device as a result.

It is noted that the processes shown in FIGS. 2 through 8 have been exemplified and explained above as the method for fabricating the MOSFET 100, the method of the invention is not limited to that. For instance, while the insulating film 26 has been formed by the two layers of film, it may be formed of a single insulating film. In this case, an insulating film of 300 nm or more is wholly formed and then the insulating film at the part where the gate electrode is to be formed may be removed to the thickness of 60 nm by etching.

Still more, while the case of using SiO₂ formed by the PCVD has been explained as the insulating film 26 in the method described above, other deposition methods such as APCVD, ECR sputtering and the like may be utilized other than the PCVD. Further, beside SiO₂, AlN, Al₂O₃, Ga₂O₃, TaOₓ or SiON that are insulating materials capable of keeping the interface state density with the channel layer 14 low and having high breakdown voltage may be used as the material of the insulating film 26.

Still more, while the ion-implantation method has been exemplified and explained as a method for forming the contact region 16b in the method described above, the invention is not limited this method and the contact region may be formed by selectively growing n′-type GaN again after removing the part where the contact region is to be formed by etching.

### Second Embodiment

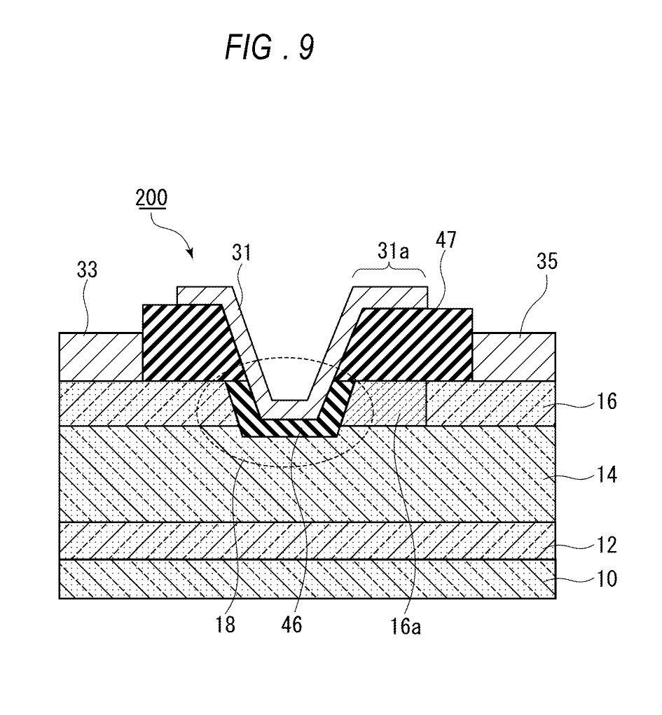

FIG. 9 is a sectional diagrammatic view of a GaN-based field effect transistor according to a second embodiment of the invention. As shown in FIG. 9, although a MOSFET 200 of the present embodiment has the similar structure with the MOSFET 100 of the first embodiment, they are different in that instead of the insulating film 26 in the first embodiment, the insulating film is composed of first insulating film 46 and second insulating film 47 in the second embodiment.

That is, the insulating film in the MOSFET 200 is composed of the first insulating film 46 formed on the inner side surface of the recess 18 and the second insulating film 47 formed on the drift layer 16. Thicknesses of the first and second insulating films 46 and 47 are 60 nm and 300 nm, respectively.

A material used for the first insulating film 46 may be what turns out as an insulating film having high breakdown voltage and SiO₂, SiN, Al₂O₃, Ga₂O₃, TaOₓ or SiON may be used. Further, a material used for the second insulating film 47 may be what turns out as an insulating film having high breakdown voltage and capable of lowering the interface state density with the drift layer 16 and SiN, Al₂O₃, Sc₂O₃ or MgO may used. Various methods such as PCVD, Cat-CVD, ECR sputtering and the like may be used for forming the first insulating film 46 and second insulating film and 47.

It is possible to simplify the process of thickening only the insulating film on the resurf region 16a by thus composing the insulating film by the first insulating film 46 and second insulating film and 47. Still more, the insulating films may be formed under the different materials and conditions such that the first insulating film 46 may be formed of the material having high breakdown voltage and the second insulating film 47 may be formed of the material having high breakdown voltage and capable of reducing the interface state density between the drift layer 16 (the resurf region 16a).

### Third Embodiment

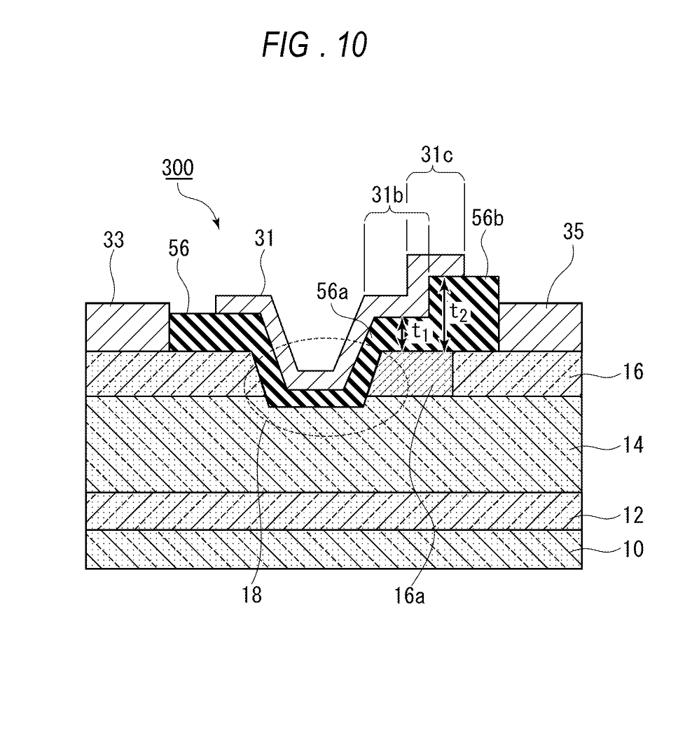

FIG. 10 is a sectional diagrammatic view of a GaN-based field effect transistor according to a third embodiment of the invention. As shown in FIG. 10, a MOSFET 300 of the third embodiment has the same structure with the MOSFET 100 of the first embodiment except of that thickness of an insulating film 56 on the resurf region 16a is increased stepwise from the side of the gate electrode 31 side.

That is, the insulating film 56 in the MOSFET 300 includes a first portion 56a where the thickness is relatively thin on the resurf region 16a and a portion 56b where the thickness is relatively thick, and a first FP portion 31b and a second FP portion 31c of the gate electrode 31 are formed thereon. Here, the thickness of the insulating film 56 is not specifically limited except of the thickest second portion 56b whose thickness ‘t₂’ is 300 nm or more. However, in view of the fabrication process, the thickness ‘t₁’ of the thin first portion 56a is preferable to be the same with that formed in the recess 18 and to be around 50 to 100 nm for example.

According to the present embodiment, the concentration of field between the gate electrode 31 and the drain electrode 35 may be dispersed by the first and second FP portions 31b and 31c, so that the withstanding voltage of the MOSFET may be improved further.

The thickness of the insulating film 56 on the resurf region 16a may be increased stepwise as described above or continuously. Still more, although a number of steps are not questioned in increasing the thickness stepwise, it is preferably two or three steps by taking a fabrication time and cost into consideration.

Although the invention has been described with respect to the specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A GaN-based field effect transistor, comprising:
a channel layer composed of p-type GaN-based compound semiconductor;
a drift layer formed on said channel layer, composed of n-type GaN-based compound semiconductor and having a concave recess that reaches said channel layer at part thereof;
source electrode and drain electrode formed on said drift layer so as to be electrically connected with said drift layer and so as to interpose said recess;
an insulating film formed on the inner surface of said recess and on the surface of said drift layer; and
a gate electrode formed on said insulating film and having a field plate portion;
wherein said drift layer has a reducing surface field region composed of n-type GaN-based compound semiconductor whose sheet carrier density is more than 5×10¹³ cm⁻² and less than 1×10¹⁴ cm⁻² between said recess and said drain electrode and thickness of said insulating film formed on said reducing surface field region of said drift layer is 300 nm or more.

2. The GaN-based field effect transistor according to claim 1, wherein said insulating film is composed of a first insulating film formed on the inner surface of said recess; and
a second insulating film formed on the surface of said drift layer.

3. The GaN-based field effect transistor according to claim 2, wherein said first insulating film is composed of SiO₂, SiN, Al₂O₃, Ga₂O₃, TaOₓ or SiON.

4. The GaN-based field effect transistor according to claim 2, wherein said second insulating film is composed of SiN, Al₂O₃, Sc₂O₃ or MgO.

5. The GaN-based field effect transistor according to claim 1, wherein the thickness of said insulating film formed on said reducing surface field region increases continuously or discontinuously from the edge on the drain electrode side of said recess toward said drain electrode and the thickness of the thickest part thereof is 300 nm or more.

6. The GaN-based field effect transistor according to claim 1, wherein the length of part of said gate electrode formed on said reducing surface field region is more than 0.5 μm and less than 10 μm.
